(19) United States
(12) Patent Application Publication
(10) Pub. No.: US 2023/0126794 A1
(43) Pub. Date: Apr. 27, 2023

(54) SEMICONDUCTOR STRUCTURE AND METHOD FOR MANUFACTURING SAME

(71) Applicant: CHANGXIN MEMORY TECHNOLOGIES, INC., Hefei City (CN)

(72) Inventor: CHIH-CHENG LIU, Hefei City (CN)

(73) Assignee: CHANGXIN MEMORY TECHNOLOGIES, INC., Hefei City (CN)

(21) Appl. No.: 17/807,847

(22) Filed: Jun. 20, 2022

Related U.S. Application Data
(63) Continuation of application No. PCT/CN2022/071851, filed on Jan. 13, 2022.

(30) Foreign Application Priority Data
Oct. 27, 2021 (CN) 202111258017.3

(51) Int. Cl. H01L 21/762

(52) U.S. Cl. CPC H01L 21/76224; H01L 21/76218; H01L 21/76256

(57) ABSTRACT

A semiconductor structure includes a substrate, comprising a first doped region; a first dielectric layer, located on the substrate; multiple deep trench capacitors, extending from the first dielectric layer to an inside of the substrate, in which each of the deep trench capacitors penetrates through the first doped region and comprises a serrated inner wall; multiple second doped regions, located in the substrate, in which each of the second doped regions surrounds a bottom of each deep trench capacitor and extends into the first doped region along an outer wall of the deep trench capacitor; and a first metal layer, located on the first dielectric layer and connected with the multiple deep trench capacitors.

### CROSS-REFERENCE TO RELATED APPLICATIONS

This is a continuation of International Application No.: PCT/CN2022/071851 filed on Jan. 13, 2022, which claims priority to Chinese Patent Application No. 202111258017.3 filed on Oct. 27, 2021. The disclosures of the above applications are hereby incorporated by reference in their entirety.

### BACKGROUND

When an integrated circuit chip, such as a dynamic random access memory (DRAM) is designed, a logic noise may reduce the speed of a circuit to generate a dynamic voltage drop and even cause a chip failure, and thus attracts people's attention. The noise in a circuit is usually reduced by a decoupling capacitor to sustain the voltage stable.

A conventional decoupling capacitor in a DRAM is a stacked decoupling capacitor (two to three stacked layers). However, the stacked decoupling capacitor makes the production process of a DRAM cell to be complicated and sensitive to the mode window and further make a process window of the decouple capacitor different from a window of a main cell array. As a result, there are often brought defects and loading effects, and the production efficiency is reduced.

### SUMMARY

The disclosure relates to the technical field of semiconductors, and particularly, but not limited, to a semiconductor structure and a method for manufacturing the same.

According to a first aspect, the embodiments of the disclosure provide a semiconductor structure, which includes a substrate, comprising a first doped region; a first dielectric layer, located on the substrate; multiple deep trench capacitors, extending from the first dielectric layer to an inside of the substrate, in which each of the deep trench capacitors penetrates through the first doped region and comprises a serrated inner wall; multiple second doped regions, located in the substrate, in which each of the second doped regions surrounds a bottom of each deep trench capacitor and extends into the first doped region along an outer wall of the deep trench capacitor; and a first metal layer, located on the first dielectric layer and connected with the multiple deep trench capacitors.

According to a second aspect, the embodiments of the disclosure provide a method for manufacturing a semiconductor structure, which includes providing a substrate, which comprises a first doped region; forming a first dielectric layer on the substrate; forming multiple deep trenches, in which the multiple deep trenches extend from the first dielectric layer to an inside of the substrate, and penetrate through the first doped region, and each of the deep trenches comprises a serrated inner wall; ion doping the substrate through the deep trenches, and performing a thermal treatment to form multiple second doped regions, in which each of the second doped regions surrounds a bottom of each of the deep trenches and extends into the first doped region along an outer wall of the deep trench; forming multiple deep trench capacitors by filling the deep trenches; and forming a first metal layer on the first dielectric layer, in which the first metal layer is connected with the multiple deep trench capacitors.

### BRIEF DESCRIPTION OF THE DRAWINGS

In the drawings (which are not necessarily drawn to scale), similar reference signs indicate similar components in different views. Similar reference signs suffixed with different letters represent similar components of different examples. The drawings illustrate each embodiment discussed herein exemplarily rather than restrictedly.

FIG. 1A is a flowchart of a method for manufacturing a semiconductor structure according to an embodiment of the disclosure.

FIG. 1B is a first structure diagram of a process for manufacturing a semiconductor structure according to an embodiment of the disclosure.

FIG. 1C is a second structure diagram of a process for manufacturing a semiconductor structure according to an embodiment of the disclosure.

FIG. 1D is a third structure diagram of a process for manufacturing a semiconductor structure according to an embodiment of the disclosure.

FIG. 1E is a fourth structure diagram of a process for manufacturing a semiconductor structure according to an embodiment of the disclosure.

FIG. 1F is a fifth structure diagram of a process for manufacturing a semiconductor structure according to an embodiment of the disclosure.

FIG. 1G is a sixth structure diagram of a process for manufacturing a semiconductor structure according to an embodiment of the disclosure.

FIG. 1H is a seventh structure diagram of a process for manufacturing a semiconductor structure according to an embodiment of the disclosure.

FIG. 1I is an eighth structure diagram of a process for manufacturing a semiconductor structure according to an embodiment of the disclosure.

FIG. 1J is a ninth structure diagram of a process for manufacturing a semiconductor structure according to an embodiment of the disclosure.

FIG. 2A is a first structure diagram of a process for manufacturing a through silicon via and a trench in a semiconductor structure according to an embodiment of the disclosure.

FIG. 2B is a second structure diagram of a process for manufacturing a through silicon via and a trench in a semiconductor structure according to an embodiment of the disclosure.

FIG. 2C is a third structure diagram of a process for manufacturing a through silicon via and a trench in a semiconductor structure according to an embodiment of the disclosure.

FIG. 2D is a first structure diagram of a process for manufacturing a deep trench capacitor and a through silicon via structure in a semiconductor structure according to an embodiment of the disclosure.

FIG. 2E is a second structure diagram of a process for manufacturing a deep trench capacitor and a through silicon via structure in a semiconductor structure according to an embodiment of the disclosure.

FIG. 2F is a structure diagram of a process for manufacturing a metal pad in a semiconductor structure according to an embodiment of the disclosure.

### DETAILED DESCRIPTION

Exemplary implementation modes of the disclosure will now be described with reference to the drawings in more detail. Although the exemplary implementation modes of the disclosure are shown in the drawings, it is to be understood that the disclosure may be implemented in various forms and are not limited to specific implementation modes described herein. Instead, these implementation modes are provided to make the disclosure understood more thoroughly and deliver the scope of the disclosure to those skilled in the art completely.

A plenty of specific details are presented in the following description so as to provide a more thorough understanding of the disclosure. However, it is apparent to those skilled in the art that the disclosure may be implemented without one or more of these details. In other examples, some known technical features in this art are not described, so as to avoid mixes with the disclosure. That is, descriptions about some features of practical embodiments and detailed descriptions about known functions and structures are omitted herein.

In the drawings, sizes of a layer, a region, and an element as well as relative sizes thereof may be exaggerated for clarity. The same reference signs represent the same elements throughout the drawings.

It is to be understood that description that an element or layer is “above”, “adjacent to”, “connected to”, or “coupled to” another element or layer may refer to that the element or layer is directly above, adjacent to, connected to, or coupled to the other element or layer, or there may be an intermediate element or layer. On the contrary, description that an element is “directly on”, “directly adjacent to”, “directly connected to”, or “directly coupled to” another element or layer refers to that there is no intermediate element or layer. It is to be understood that, although various elements, components, regions, layers, and/or parts may be described with terms first, second, third, etc., these elements, components, regions, layers, and/or parts are not limited to these terms. These terms are used only to distinguish one element, component, region, layer, or part from another element, component, region, layer, or part. Therefore, a first element, component, region, layer, or part discussed below may be represented as a second element, component, region, layer, or part without departing from the teaching of the disclosure. When the second element, component, region, layer, or part is discussed, it does not indicate that the first element, component, region, layer, or part necessarily exist in the disclosure.

The terms used herein are only for a purpose of describing specific embodiments and not intended to limit the disclosure. As used herein, singular forms “a/an”, “one”, and “the” are also intended to include plural forms, unless otherwise specified in the context. It is also to be understood that, when terms “composed of” and/or “including” are used in this specification, the existence of the features, integers, steps, operations, elements, and/or components is determined, but the existence or addition of one or more other features, integers, steps, operations, elements, components, and/or groups is also possible. As used herein, term “and/or” includes any and all combinations of related listed items.

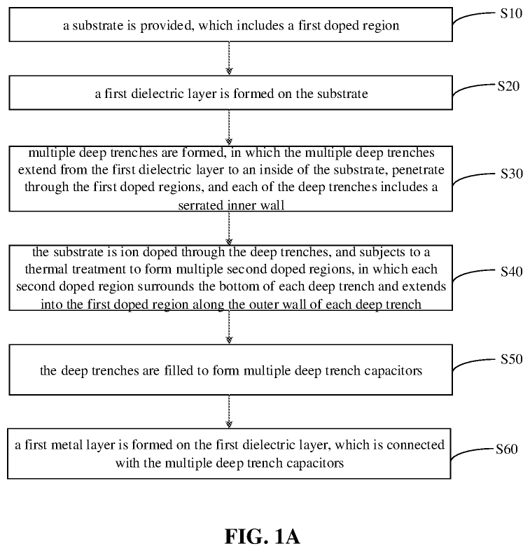

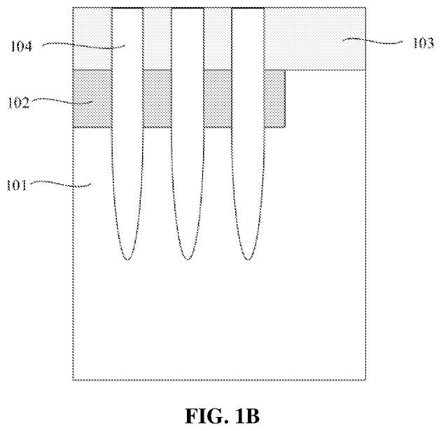

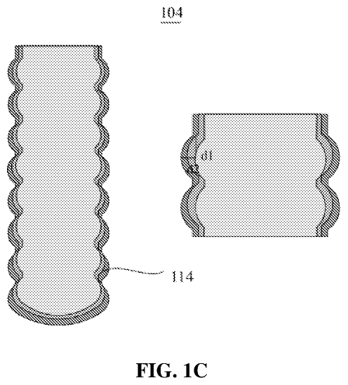

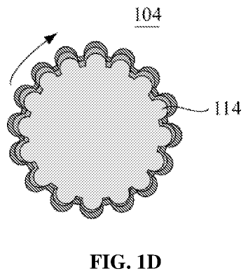

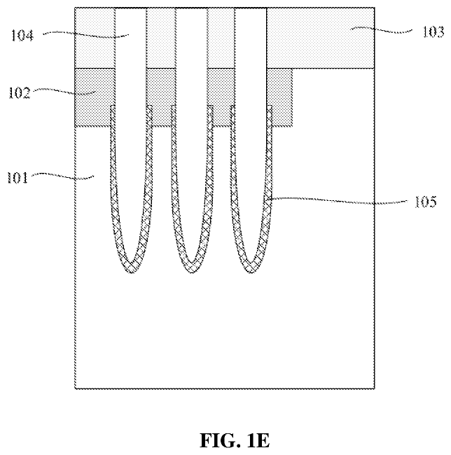

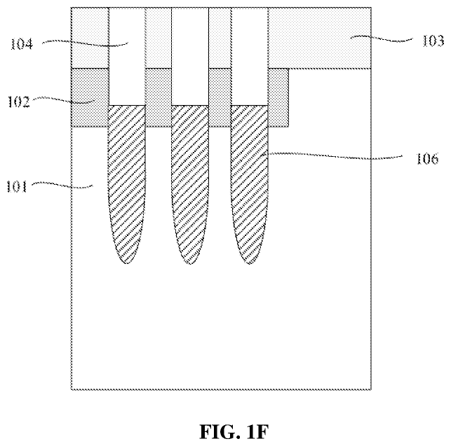

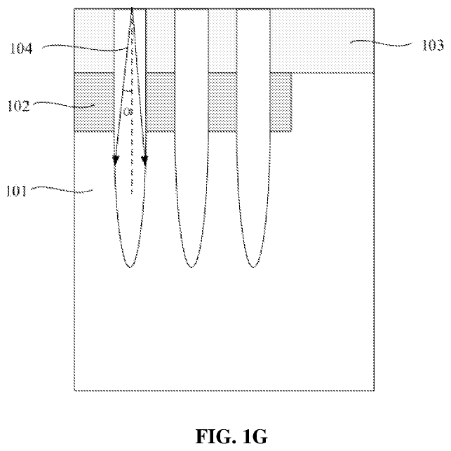

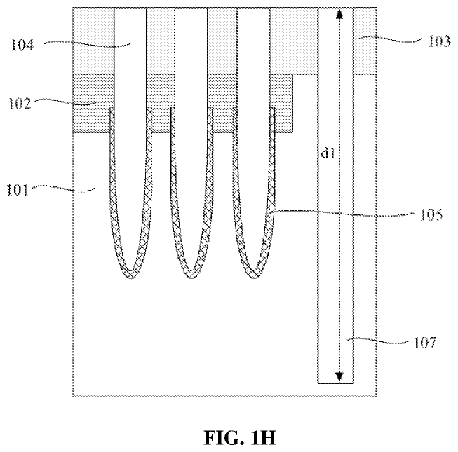

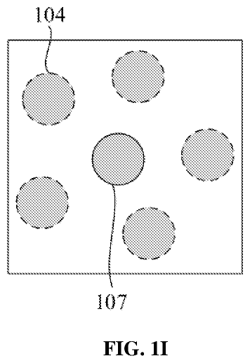

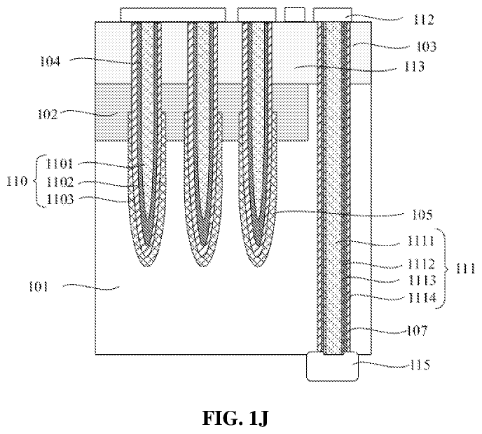

An embodiment of the disclosure provides a method for manufacturing a semiconductor structure. As shown in FIG. 1A, the method includes the following operations.

In S10, a substrate is provided, which includes a first doped region.

As shown in FIG. 1B, a substrate 101 includes the first doped region 102.

Here, the substrate may be a silicon (Si) substrate, a germanium (Ge) substrate, a silicon-germanium (SiGe) substrate, a gallium arsenide substrate, a ceramic substrate, a quartz substrate, or a glass substrate for a display, or may include multiple layers, such as a silicon on insulator (SOI) substrate or a germanium on insulator (GOI) substrate.

The first doped region is configured to form an active device. For example, it may be an n-type doped region, and may be doped with phosphorus (P), arsenic (As), boron (B), or other proper elements.

During implementation, the first doped region (active area) may be formed by ion implantation in a region for forming the active device on the substrate. In some embodiments, a shallow trench isolation may be formed first on the substrate, and then the first doped region is formed. That is, the first doped region is separated by the shallow trench isolation.

In S20, a first dielectric layer is formed on the substrate.

As shown in FIG. 1B, a first dielectric layer 103 is formed on the substrate 101.

Here, a material of the first dielectric layer may be silicon dioxide (SiO₂) or another insulating material. A process for depositing the material of the first dielectric layer on the substrate may include chemical vapor deposition (CVD), physical vapor deposition (PVD), or atomic layer deposition (ALD).

In S30, multiple deep trenches are formed, in which the multiple deep trenches extend from the first dielectric layer to an inside of the substrate, penetrate through the first doped regions, and each of the deep trenches includes a serrated inner wall.

In some embodiments, each of the deep trenches includes a serrated inner wall with multiple recesses.

As shown in FIG. 1B, multiple deep trenches 104 are formed after the first dielectric layer 103 is formed. Here, the multiple deep trenches may include one deep trench, or at least two deep trenches. The figure takes three deep trenches as an example for illustration. The multiple deep trenches 104 extend from the first dielectric layer 103 into the inside of the substrate 101. The deep trenches 104 penetrate through the first doped region 102. Each deep trench 104 includes a serrated inner wall with multiple recesses.

In some embodiments, the serrated inner wall with the multiple recesses may include one recess, or at least two recesses. The recesses may be arranged in a regular pattern, or in an irregular pattern, or partially in a regular pattern and partially in an irregular pattern.

In some embodiments, the recesses are arranged in a regular pattern. As shown in FIG. 1C (a sectional view of a deep trench 104 in a direction perpendicular to the substrate 101), the arranged pattern of recesses 114 is recess layers stacked in a first direction. FIG. 1D is a top view of a recess layer. Each recess layer includes recess structures arranged in a third direction.

The first direction is the depth direction of the deep trenches 104 (i.e., a vertical direction in FIG. 1C). The third direction is a circumferential direction of the recess layers (i.e., the direction as the arrow shown in FIG. 1D).

In some embodiments, the recess structures may include elliptical recesses, and/or spherical recesses.

As shown in FIG. 1C, the length d1 of a recess 114 in the first direction ranges from 0.2 to 0.6 microns, and the length d2 of the recess 114 in the second direction ranges from 0.1 to 0.4 microns. The first direction is the depth direction of the deep trench. The second direction is the horizontal direction. Such a structure may enlarge the surface area of a deep trench capacitor, thereby enlarging the opposite area between two electrodes of the deep trench capacitor. Therefore, capacitance of the deep trench capacitor is increased, thereby stabilizing the voltage.

Here, the substrate and the first dielectric layer may be etched by a dry etching process, so as to form the trenches. The dry etching process may be a plasma etching process, a reactive ion etching process, or an ion milling process. Alternatively, the substrate and the dielectric layer may be etched by deep reactive ion etching (DRIE), so as to obtain a through via. The DRIE technology cyclically and alternately implements two processes of depositing a polymer passivation layer and etching mono-crystalline silicon, thereby avoiding influences between the deposition and the etching, and ensuring the stability and reliability of the passivation layer to further form a high-aspect-ratio scallop structure with a steep sidewall. In the embodiment of the disclosure, the Si surface may be etched first by sulfur hexafluoride (SF₆). Then a layer of polyfluorocarbon ((CF)ₙ) polymer passivation film is deposited on the sidewall. Next, SF₆ is introduced to etch away the passivation film. Later on, the Si substrate is etched. The etching and deposition processes are performed alternately to achieve a ripple effect on the etched surface of the sidewall.

In S40, the substrate is ion doped through the deep trenches, and subjects to a thermal treatment to form multiple second doped regions, in which each second doped region surrounds the bottom of each deep trench and extends into the first doped region along the outer wall of each deep trench.

As shown in FIG. 1E, the ion doping is performed on the substrate 101 through the deep trenches 104, and the thermal treatment is performed to form multiple second doped regions 105. Each of the second doped regions 105 surrounds the bottom of each of the deep trenches 104, and extends into the first doped region 102 along the outer wall of each deep trench 104.

In some embodiments, the second doped regions may be formed by vapor doping. During implementation, as shown in FIG. 1F, the openings of the deep trenches 104 are exposed to a high-concentration doping gas 106, such as P or As, and the gas 106 is diffused into the substrate 101 to form the second doped regions 105 in FIG. 1E.

In some embodiments, the second doped regions 105 may further extend into the first doped region 102 along the outer walls of the deep trenches 104, and contact with the top of the first doped region 102, thereby enlarging the area of each second doped region 105 surrounding each deep trench 104. Therefore, the area of an electrode of a subsequently formed deep trench capacitor may be enlarged, and furthermore, a voltage stabilization effect of the deep trench capacitor may be improved.

In some other embodiments, the second doped regions may be formed by the ion implantation. During implementation, a dopant such as P or As is implanted at an angle. For example, the dopant may be implanted to the bottom of a deep trench at an incidence angle of, for example, 5° or 3°, according to the depth of the deep trench. As shown in FIG. 1G, the dopant is implanted to the bottoms of the deep trenches 104 at the incidence angle α, so as to form the second doped regions 105 in FIG. 1E.

Here, thermal treatment may not only accelerate diffusion but also recover lattice defects caused by the ion implantation.

It is to be noted that the manner for forming the second doped region is not limited in the embodiment of the disclosure.

In some embodiments, an ion doping dose of the first doped region is less than that of the second doped region. Therefore, the second doped region is a heavily doped region. In such case, the second doped region (external electrode) is grounded, and an internal electrode is connected with a positive voltage. As such, depletion in the second doped region may be prevented, and formation of a depletion region is avoided, and therefore, a depletion effect of a deep trench capacitor is reduced, and the capacitance value of the deep trench capacitor is stabilized.

In some embodiments, the ion doping type of the first doped region is the same as that of the second doped region. For example, if the ion doping type of the first doped region is N type, the ion doping type of the second doped region is also N type. Therefore, conductivity between the first doped region and the second doped region may be achieved and thus together form the external electrode of a deep trench capacitor.

In some embodiments, after S40, the method further includes S401. In S401, a through silicon via is formed, the through silicon via penetrates the first dielectric layer and the substrate, the multiple deep trenches are located on a periphery of the through silicon via, and the through silicon via includes a serrated inner wall.

As shown in FIG. 1H, the silicon through via 107 penetrating the first dielectric layer 103 and the substrate 101 is formed. Here, the through silicon via is a through via formed in the chip and penetrates through the substrate of the chip. The through silicon via is filled with a conductive material to transmit a signal from the front surface of the chip to the back surface of the chip.

The through silicon via 107 shown in FIG. 1H does not penetrate through the substrate 101. In a practical operation process, for a relatively thick substrate 101, a through silicon via 107 with a preset depth may be formed first by etching, and then the part of the substrate 101, where the through silicon via 107 does not penetrate through, is removed by a substrate thinning process (such as mechanical grinding, chemical mechanical polishing (CMP), and wet etching), such that the through silicon via penetrates the substrate 101.

The through silicon via 107 is located at a side of the first doped region 102, namely located in the shallow trench isolation. The through silicon via 107 does not overlap the first doped region 102.

In some embodiments, the through silicon via may be located in the first doped region. When the second doped regions and the first doped region form an electrode (such as the external electrode) of the decoupling capacitor, the through silicon via may not only transmit a signal from the front surface of the chip to the back surface of the chip, but also serve as the other electrode (such as the internal electrode) of the decoupling capacitor. Therefore, the area of this electrode may be enlarged. That is, an opposite area of the decoupling electrodes may be enlarged. As such, the voltage may be stabilized.

In some embodiments, the through silicon via may be formed by a dry etching process, and has a serrated inner wall with the same pattern as the deep trenches.

As shown in FIG. 1H, the multiple deep trenches 104 (three deep trenches 104 are taken as an example for illustration in this figure) are located on a periphery of the through silicon via 107. The through silicon via 107 also includes a serrated inner wall (not shown in the figure). A structure of the serrated inner wall of the through silicon via 107 is the same as that of the serrated inner wall of the deep trench in FIGS. 1C and 1D.

In some embodiments, the multiple deep trenches 104 are located on the periphery of the through silicon via 107, so that deep trench capacitors are located on the periphery of the through silicon via structure. Therefore, these deep trench capacitors may effectively absorb the stress diffused during the formation of the through silicon via structure and prevent formation of a crack between the through silicon via structure and a semiconductor structure around it. As such, the through silicon via structure may be protected, and the performance of the semiconductor structure may further be improved.

In some embodiments, as shown in FIG. 1I, the multiple deep trenches 104 may be located in a circle on the periphery of the through silicon via 107. The arrangement of multiple deep trench capacitors may stabilize the voltage better.

During implementation, the through silicon via and the multiple deep trenches may be formed at the same time. For example, first blind holes with the same depth are formed first to form the deep trenches. Then, one of the first blind holes continues to be etched to a preset depth to obtain the through silicon via.

Certainly, the through silicon via and the multiple deep trenches may also be formed respectively. That is, the through silicon via is formed after the multiple deep trenches are formed. In such case, the through silicon via may be etched directly to the preset depth.

In S50, the deep trenches are filled to form multiple deep trench capacitors.

As shown in FIG. 1J, the deep trenches 104 are filled to form multiple deep trench capacitors 110.

Here, a deep trench capacitor may include a first insulating layer, a buffer layer, and a first conductive layer. The material of the first insulating layer may include SiO₂. The material of the buffer layer may include metallic tantalum or tantalum nitride. The material of the first conductive layer may include metallic Cu, or metallic W, or metallic Al.

If the through silicon via is formed, S50 further includes that: the through silicon via is filled to form a through silicon via structure.

As shown in FIG. 1J, the through silicon via 107 is filled to form a through silicon via structure 111.

Here, the through silicon via structure may include a second insulating layer, a barrier layer, a seed layer, and a second conductive layer. The material of the second insulating layer may include SiO₂. The material of the barrier layer may include metallic tantalum or tantalum nitride. The material of the seed layer may include metallic W, Co, Cu, Al, or any combination thereof. The material of the second conductive layer may include metallic Cu or metallic W.

In some embodiments, the depth of the through silicon via structure ranges from 40 to 60 microns, for example, 50 microns. The depth of the deep trench capacitor ranges from 10 to 20 microns, for example, 15 microns.

In such case, the deep trench capacitors do not penetrate the substrate. Since the depth of the deep trench capacitors is relatively small, process difficulties may be reduced. During implementation, the multiple deep trench capacitors may be arranged as required to stabilize the voltage.

In S60, a first metal layer is formed on the first dielectric layer, which is connected with the multiple deep trench capacitors.

As shown in FIG. 1J, a first metal layer 112 is formed on the first dielectric layer 103. The first metal layer 112 is connected with the multiple deep trench capacitors 104.

Here, the material of the first metal layer may include W, Co, Cu, Al, polysilicon, doped Si, silicide, or any combination thereof. The first metal layer is connected with the multiple deep trench capacitors. That is, the first metal layer is connected with the first conductive layers of the multiple deep trench capacitors, thereby achieving conductivity between the first metal layer and the first conductive layers.

In the case that the through silicon via structure is formed, as shown in FIG. 1J, the first metal layer 112 is further connected with one end of the through silicon via structure 111. The other end of the silicon through via structure 111 is connected with a metal bump 115.

Here, one end of the through silicon via structure is connected with the first metal layer, while the other end is connected with the metal bump, thereby transmitting a signal from the front surface of the chip to the back surface of the chip.

In some embodiments, when the second doped regions and the first doped region form one electrode of the decoupling capacitors, the through silicon via structure may serve as the other electrode of the decoupling capacitors to stabilize the voltage.

In some embodiments, a second doped region may surround the through silicon via structure, and is connected with the first doped region. Therefore, the through silicon via structure may serve as a decoupling capacitor, also playing a role of stabilization of the voltage.

The material of the metal bump may include nickel (Ni), a nickel alloy, Cu, a copper alloy, palladium (Pd), platinum (Pt), gold (Au), Co, or any combination of these materials.

In some embodiments, the metal bump may serve as a pad to enable stacking between active devices.

In the embodiment of the disclosure, first, the first conductive layer of a deep trench capacitor is connected with the first metal layer to form the internal electrode of the deep trench capacitor, and the second doped region at the bottom of the deep trench extends into the first doped region to form the external electrode of the deep trench capacitor together. The first insulating layer in the deep trench capacitor serves as a dielectric layer between the internal electrode and the external electrode. Since the deep trench includes the serrated inner wall, the surface area of the first insulating layer is enlarged. Meanwhile, the first conductive layer is arranged conformally on the first insulating layer, so that the surface area of the first conductive layer is also enlarged. Therefore, the opposite area between the external electrode and the internal electrode is enlarged, capacitance of the deep trench capacitor is increased, and the voltage is stabilized. Second, the existence of the high-concentration second doped region reduces the depletion effect of the deep trench capacitor, and stabilizes the capacitance value of the deep trench capacitor. Finally, in the embodiments of the disclosure, the deep trench capacitor is used as a decoupling capacitor, so that the production process is simple, defects can be readily avoided, and the production efficiency is improved.

In some embodiments, implementation of S30 that “multiple deep trenches are formed, which extend from the first dielectric layer to an inside of the substrate, and penetrate through the first doped region, in which each of the deep trenches includes a serrated inner wall” and S401 that “a through silicon via is formed, which penetrates through the first dielectric layer and the substrate, in which the multiple deep trenches are located on a periphery of the through silicon via, and the through silicon via includes a serrated inner wall” includes the following operations.

In S301, the first dielectric layer and the substrate are etched to form multiple trenches, bottoms of the trenches are at a preset distance from a bottom of the substrate.

Here, the preset distance may be determined according to the thickness of the substrate. The preset distance is equal to the thickness of the substrate minus the depth of the deep trench capacitor. In some embodiments, the depth of the deep trench capacitor ranges from 10 to 20 microns.

In S302, a number of the trenches are covered, an exposed trench continues to be etched to penetrate the substrate so as to form the through silicon via, and the covered the trenches are defined as the deep trenches.

In some embodiments, implementation of S301 that “the first dielectric layer and the substrate are etched to form multiple trenches, the bottom of the trenches are at the preset distance from the bottom of the substrate” includes the following operations.

In S301a, a first photoresist layer is formed on the substrate.

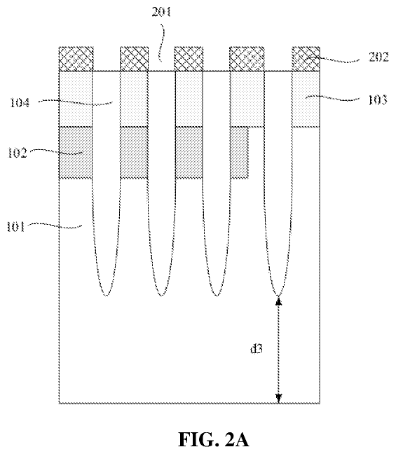

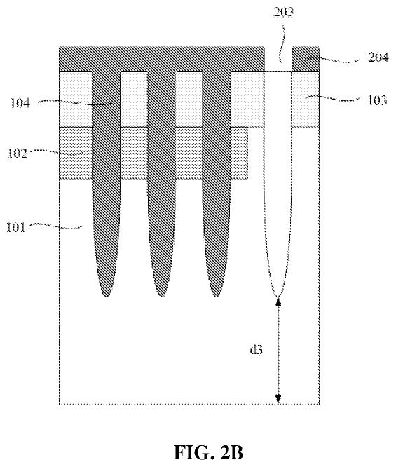

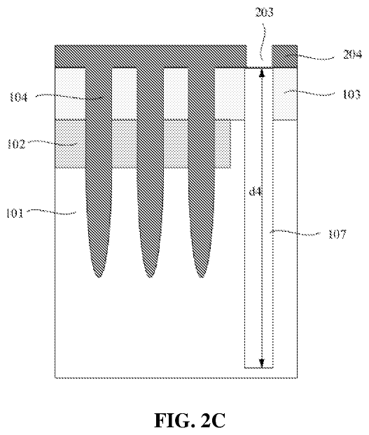

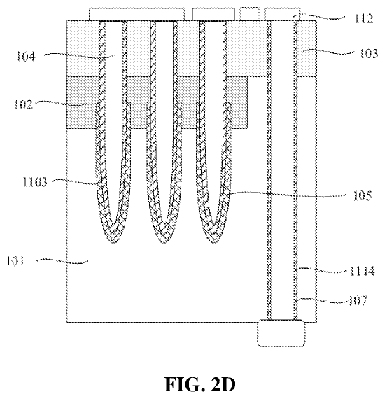

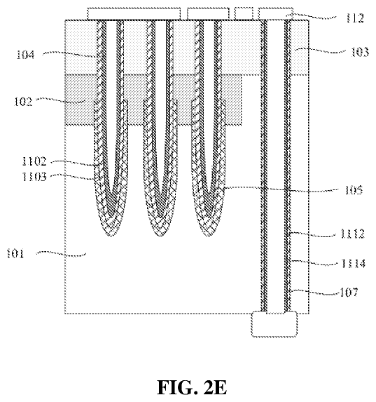

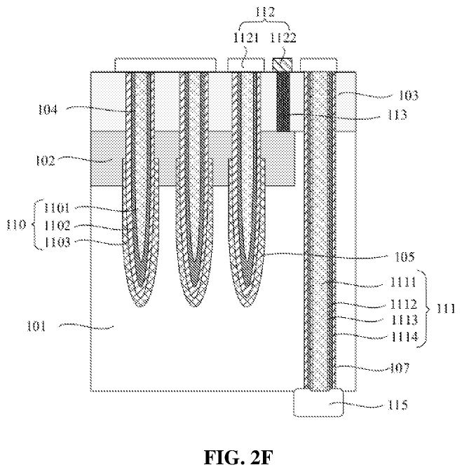

As shown in FIG. 2A, a first photoresist layer 202 is formed on the substrate 101.

Here, the first photoresist layer is formed on the silicon substrate by a spin-coating process. The material of the first photoresist layer may be a photoresist composed of a novolac resin, a photosensitive naphthoquinone diazo compound such as diazo naphtho quinone (DNQ), a solvent for adjusting viscosity and other physicochemical properties, and an additive, alternatively, may be a photoresist material of a chemically amplification photoresist (CAMP) system, or a chemically amplified photoresist.

In S301b, the first photoresist layer is patterned to form first windows, the first windows expose positions corresponding to the multiple trenches.

As shown in FIG. 2A, the first photoresist layer 202 is patterned to form first windows 201. The first windows 201 expose positions corresponding to the multiple trenches 104.

In some embodiments, the first photoresist layer may be subjected to a patterning treatment by exposure, development, and other operations, so as to form the first windows. In practical applications, a mask and the substrate are aligned such that the first photoresist layer is subject to an exposure to obtain the first windows, and the finally formed multiple trenches are located at the preset positions.

In S301c, the substrate and the first dielectric layer are etched through the first windows by taking the first dielectric layer as the etching starting point to form the multiple trenches of which the bottoms are at the preset distance from the bottom of the substrate.

As shown in FIG. 2A, the substrate 101 and the first dielectric layer 103 are etched through the first windows 201 by taking the first dielectric layer 103 as the etching starting point to form the multiple trenches 104 of which the bottoms are at a preset distance d3 from the bottom of the substrate 101. Then, the first photoresist layer 202 is removed by a wet etching process or a dry etching process.

In some embodiments, the preset distance d3 is equal to the thickness of the substrate minus a depth of the deep trench capacitor. The depth of the deep trench capacitor ranges from 10 to 20 microns.

Here, the substrate and the first dielectric layer may be etched by a dry etching process, so as to form the trench.

In some embodiments, the first photoresist layer may be removed by a wet etching process or a dry etching process.

In some embodiments, implementation of S302 that “a number of the trenches are covered, an exposed trench continues to be etched to penetrate through the substrate so as to form the through silicon via, and the covered the trenches are defined as the deep trenches” includes the following operations.

In S302a, a second photoresist layer is formed on the substrate where the multiple trenches are formed.

As shown in FIG. 2B, a second photoresist layer 204 is formed on the substrate 101 where the multiple trenches 104 are formed.

In S302b, the second photoresist layer is patterned to form a second window which exposes a position corresponding to the through silicon via and covers positions except for the through silicon via.

As shown in FIG. 2B, the second photoresist layer 204 is patterned to form the second window 203. The second window 203 exposes the position corresponding to the through silicon via. The patterned second photoresist layer 204 covers positions except for the through silicon via.

In S302c, the substrate is etched through the second window by taking the bottom of the trench as an etching starting point to form the through silicon via having a preset depth, and the trenches covered by the second photoresist layer are defined as the deep trenches.

As shown in FIG. 2B, the substrate 101 is etched to be penetrated through the second window 203 by taking the bottom of the trench 104 as the etching starting point to form the through silicon via 107 with the preset depth d4, as shown in FIG. 2C. The trenches 104 covered by the second photoresist layer 204 are simultaneously defined as the deep trenches 104. Then, the second photoresist layer 204 is removed by a wet etching process or a dry etching process.

Here, implementation of S302a to S302c refers to S301a to S301c. The material of the second photoresist layer may be the same as or different from that of the first photoresist layer. The etching process for forming the through silicon via may be the same as or different from that for forming the deep trench.

In some embodiments, the second photoresist layer may be removed by a wet etching process or a dry etching process.

Correspondingly, under the situation that the trench corresponding to the through silicon via is formed while the multiple trenches are formed, the second doped region may be formed by ion implantation. Therefore, the operation of protecting the through silicon via when adopting vapor doping is omitted.

In the embodiment of the disclosure, the trench corresponding to the through silicon via is formed while the multiple trenches are formed, and then the trench corresponding to the through silicon via is etched again to the preset depth to obtain the through silicon via. As such, the technological process can be simplified, the process complexity is reduced, product defects are reduced, and the production efficiency is improved.

In some embodiments, implementation of S30 that “multiple deep trenches are formed, which extend from the first dielectric layer to an inside of the substrate, and penetrate through the first doped region, in which each of the deep trenches includes a serrated inner wall” and S401 that “the through silicon via is formed, which penetrate through the first dielectric layer and the substrate, in which the multiple deep trenches are located on a periphery of the through silicon via, and the through silicon via includes a serrated inner wall” further includes the following operations.

In S311, the first dielectric layer and the substrate are etched to form multiple trenches, and a bottom of the trench is at a preset distance from a bottom of the substrate.

Here, implementation of S311 refers to S301.

In S312, the first dielectric layer and the substrate are etched to form the through silicon via, in which a depth of the through silicon via is a preset depth.

Here, the through silicon via may be formed after the multiple second doped regions are formed.

A method for forming the through silicon via refers to S302a to S302c. That is, an opening corresponding to the through silicon via is formed by a photoresist, and then the through silicon via is formed by etching.

In the embodiment of the disclosure, the through silicon via may be formed after the multiple second doped regions are formed. As such, the through silicon via needs not to be protected independently during the formation of the second doped regions by vapor doping. Therefore, the process is simplified, the process complexity is reduced, product defects are reduced, and the production efficiency is improved.

In some embodiments, implementation of S50 that “the deep trenches are filled to form multiple deep trench capacitors” includes the following operations.

In S501, a first insulating layer is formed in the deep trenches, the first insulating layer is lined the serrated inner wall.

As shown in FIG. 1J, a first insulating layer 1103 is formed in each deep trench 104. The first insulating layer 1103 is conformally lined the serrated inner wall (not shown in the figure).

Here, the first insulating layer is configured to block the conduction between the subsequently filled metal and the substrate and protect the substrate from being damaged. The material of the first insulating layer may be silicon oxide, silicon nitride, a polymer or the like. Different insulating layer materials need different deposition technologies. The material of SiO₂ may be deposited by a thermal oxidation technology. The material of SiO₂ and the material of Si₃N₄ may be deposited by a plasma enhanced chemical vapor deposition (PECVD) technology. The material of paraxylene may be deposited by a vacuum vapor deposition technology.

In some embodiments, the thickness of the first insulating layer ranges from 100 to 300 nm, for example, 200 nm. Therefore, electric leakage caused by surface inhomogeneity of the first insulating layer may be reduced.

In some embodiments, the breakdown voltage of the deep trench capacitor is equal to or more than 10 volts.

In S502, a first buffer layer is formed on the first insulating layer.

As shown in FIG. 1J, a first buffer layer 1102 is formed on the first insulating layer 1103.

Here, the first buffer layer is configured to prevent diffusion of the conductive material subsequently filled the deep trench. The material of the first buffer layer may be metallic tantalum, tantalum nitride, titanium nitride, or the like. The first buffer layer may be formed by any proper deposition process.

In S503, a first conductive layer is formed on the first buffer layer.

As shown in FIG. 1J, a first conductive layer 1101 is formed on the first buffer layer 1102.

The first conductive layer 1101 is connected with the first metal layer 112 to form an external electrode of the deep trench capacitor 110. Here, the material of the first conductive layer may be any conductive metal, such as W, Co, Cu, Al, polysilicon, doped silicon, silicide, or any combination thereof. Generally, the material of the first conductive layer is metallic Cu. A layer of Cu is deposited by electro chemical plating (ECP) to form the first conductive layer.

Under the situation that the through silicon via is formed, implementation of S50 that “the through silicon via is filled to form a through silicon via structure” includes the following operations.

In S511, a second insulating layer is formed in the through silicon via, in which the second insulating layer is lined the serrated inner wall.

As shown in FIG. 2D, the first insulating layer 1103 is formed in each deep trench 104, in which the first insulating layer 1103 is conformally lined the serrated inner wall (not shown in the figure). Meanwhile, a second insulating layer 1114 is formed in the through silicon via 107, in which the second insulating layer 1114 is conformally lined the serrated inner wall (not shown in the figure).

Here, the second insulating layer is configured to block the conduction between the subsequently filled metal and the substrate and protect the substrate from being damaged. The material of the second insulating layer may be silicon oxide, silicon nitride, a polymer or the like. Different insulating layer materials need different deposition technologies. The material of SiO₂ may be deposited by a thermal oxidation technology. The material of SiO₂ and the material of Si₃N₄ may be deposited by a PECVD technology. The material of paraxylene may be deposited by a vacuum vapor deposition technology.

In S512, a second buffer layer is formed on the second insulating layer.

As shown in FIG. 2E, a second buffer layer 1112 is formed on the second insulating material 1114 while the first buffer 1102 is formed on the first insulating layer 1103. Here, the second buffer layer is configured to prevent diffusion of the conductive material subsequently filled the deep trench. The material of the second buffer layer may be metallic tantalum, tantalum nitride, titanium nitride, or the like. The first buffer layer may be formed by any proper deposition process.

In S513, a second conductive layer is formed on the second buffer layer.

The through silicon via structure and the deep trench capacitor are formed at the same time.

In some embodiments, the through silicon via structure may further include a seed layer. The seed layer is formed on the second buffer layer. The second conductive layer is formed on the seed layer.

As shown in FIG. 1J, a seed layer 1113 may be formed first on the second buffer layer 1112. Then, a second conductive layer 1111 is formed on the seed layer 1113 while the first conductive layer 1101 is formed on the first buffer layer 1102.

Here, the material of the second conductive layer may be any conductive material, such as W, Co, Cu, Al, polysilicon, doped Si, silicide, or any combination thereof. A second conductive material may be the same as or different from the seed material. The material of the second conductive layer is, for example, metallic Cu, so that a Cu conductive layer is formed. The seed layer may be deposited first by PVD as a cathode of electroplating, and a layer of Cu is deposited by ECP to form the second conductive layer.

In the embodiment of the disclosure, forming the through silicon via structure and the deep trench capacitors at the same time further simplifies the process flow, thereby reducing the process complexity, reducing product defects, and improving the production efficiency.

In some embodiments, S20 that “a first dielectric layer is formed on the substrate” further includes that: a metal pad is formed in the first dielectric layer, in which the first metal layer is connected with the first doped region through the metal pad to form an external electrode of the deep trench capacitor, which includes the following operations.

In S201, a third photoresist layer is formed on the substrate.

In S202, the third photoresist layer is patterned to form a third window, the third window exposing a position corresponding to the metal pad.

In S203, a metal pad hole penetrating through the first dielectric layer is etched through the third window by taking the first dielectric layer as an etching starting point.

Here, implementation of S201 to S203 refers to S301a to S301c.

In S204, the metal pad is formed in the metal pad hole, in which the metal pad connects the first metal layer and the first doped region to form the external electrode of the deep trench capacitor.

Here, the metal pad may be formed in the metal pad hole by CVD. The material of the metal pad may be metallic W.

It is to be noted that the internal electrode of each deep trench capacitor is formed by the first conductive layer and the first metal layer, while the external electrode is formed by the first doped region, the metal pad and the first metal layer. Therefore, the first metal layer at least includes a first metal sub-block and a second metal sub-block. The first metal sub-block is connected with the first conductive layer, and the second metal sub-block is connected with the metal pad. As such, the internal electrode is insulated from the external electrode. The internal electrode is, for example, an anode. The external electrode is, for example, a cathode.

Referring to FIG. 2F, a metal pad 113 connects a first metal sub-block 1122 and the first doped region 102 to form the external electrode of the deep trench capacitors. The first conductive layer 1101 is connected with a second metal sub-block 1121 to form the internal electrode of each deep trench capacitor 110.

In some embodiments, the first metal layer 112 further connects the through silicon via structure 111 to transmit a signal from the front surface of a chip to the back surface of the chip.

In the embodiment of the disclosure, the metal pad is formed in the first dielectric layer, and thus a connection between the first doped region and the first metal layer is achieved. Different voltages are biased on the first metal layer to achieve an electric field between the internal and external electrodes to form the decoupling capacitor, thereby stabilizing the voltage.

In some embodiments, implementation of S60 that “a first metal layer is formed on the first dielectric layer, the first metal layer is connected with the multiple deep trench capacitors” includes the following operations.

In S601, a second dielectric layer is formed on the first dielectric layer.

Here, the material of the second dielectric layer may be the same as or different from that of the first dielectric layer.

In S602, a fourth photoresist layer is formed on the second dielectric layer.

In S603, the fourth photoresist layer is patterned to form a fourth window, the fourth window exposing a position corresponding to the first metal layer.

In S604, the second dielectric layer is etched through by the fourth window by taking the second dielectric layer as an etching starting point to form the second dielectric layer with a first metal pattern.

Here, implementation of S602 to S604 refers to S301a to S301c.

In S605, the first metal layer is formed by a deposition process.

Here, the material of the first metal layer may be W, Co, Cu, Al, polysilicon, doped Si, silicide, or any combination thereof.

The embodiment of the disclosure also provides a method for manufacturing a semiconductor structure, which includes the following operations.

In S801, referring to FIG. 1B, a substrate 101 is provided, and the substrate 101 includes a first doped region 102.

In S802, referring to FIG. 1B, a first dielectric layer 103 is formed on the substrate 101.

In S803, referring to FIG. 1B, multiple deep trenches 104 (the figure takes three deep trenches as an example for description) are formed. Here, a depth of the deep trenches 104 ranges from 10 to 20 microns, the multiple deep trenches 104 extend from the first dielectric layer 103 to an inside of the substrate 101, the deep trenches 104 penetrate through the first doped region 102, and each of the deep trenches 104 includes a serrated inner wall with multiple recesses 114 shown in FIG. 1C (a sectional view of a deep trench 104 in the direction perpendicular to the substrate 101).

In some embodiments, the recesses are arranged in a regular pattern, and recess layers are stacked in the depth direction of a deep trench. Each recess layer includes recess structures arranged in a horizontal direction. The recess structures include elliptical recesses and/or spherical recesses.

The length of a recess 114 in the depth direction of a deep trench ranges from 0.2 to 0.6 microns. The length of the recess 114 in the horizontal direction ranges from 0.1 to 0.4 microns.

In S804, referring to FIGS. 1E and 1F, openings of the deep trenches 104 are exposed to a high-concentration doping gas 106 such as P or As, and the gas 106 is diffused into the substrate 101 to form the second doped region 105 in FIG. 1E.

In S805, referring to FIG. 1H, the through silicon via 107 penetrating through the first dielectric layer 103 and the substrate 101 is formed, and the depth of the through silicon via ranges from 40 to 60 microns.

In S806, referring to FIG. 2D, a first insulating layer 1103 is formed in each deep trench 104, the first insulating layer 1103 is lined the serrated inner wall (not shown in the figure), and meanwhile, a second insulating layer 1114 is formed in the through silicon via 107, the second insulating layer 1114 is lined the serrated inner wall (not shown in the figure). Here, the thickness of the first insulating layer ranges from 100 to 300 nm, and a breakdown voltage of a deep trench capacitor is more than or equal to 10 volts.

In S807, referring to FIG. 2E, a first buffer layer 1102 is formed on the first insulating layer 1103, and meanwhile, a second buffer layer 1112 is formed on the second insulating layer 1114.

In S808, referring to FIG. 1J, a seed layer 1113 is formed on the second buffer layer 1112.

In S809, referring to FIG. 1J, a first conductive layer 1101 is formed on the first buffer layer 1102, and meanwhile, a second conductive layer 1111 is formed on the seed layer 1113.

In S810, referring to FIG. 2F, a metal pad 113 is formed in the first dielectric layer 103.

In S811, referring to FIG. 2F, a first metal layer 112 is formed on the first dielectric layer 103, in which the first metal layer 112 at least includes a first metal sub-block 1122 and a second metal sub-block 1121. Here, the metal pad 113 is connected with the first metal sub-block 1122 and the first doped region 102 to form an external electrode of the deep trench capacitors 110, and a first conductive layer 1101 is connected with the second metal sub-block 1121 to form an internal electrode of a deep trench capacitor 110.

Based on the above-mentioned method, an embodiment of the disclosure provides a semiconductor structure. As shown in FIG. 2F, the semiconductor structure includes the following parts.

A substrate 101 includes a first doped region 102.

A first dielectric layer 103 is located on the substrate 101.

In some embodiments, a metal pad 113 is included in the first dielectric layer 103. A first metal layer 112 is connected with the first doped region 102 through the metal pad 113 to form an external electrode of the deep trench capacitors 110.

Multiple deep trenches 110 extend from the first dielectric layer 103 to an inside of the substrate 101. Each of the deep trench capacitors 110 penetrates through the first doped region 102. Each of the deep trench capacitors 110 includes a serrated inner wall.

In some embodiments, each of the deep trench capacitors 110 includes the serrated inner wall with multiple recesses.

In some embodiments, the length d1 of a recess 114 in a first direction ranges from 0.2 to 0.6 microns. The length d2 of the recess 114 in a second direction ranges from 0.1 to 0.4 microns.

Each deep trench capacitor 110 includes a first insulating layer 1103 lining the serrated inner wall, a first buffer layer 1102 located on the first insulating layer 1103, and a first conductive layer 1101 located on the first buffer layer 1102. The first conductive layer 1101 is connected with the first metal layer 112 to form an internal electrode of the deep trench capacitor 110.

In some embodiments, the thickness of the first insulating layer ranges from 100 to 300 nm.

Multiple second doped regions 105 are located in the substrate 101. Each of the second doped regions 105 surrounds the bottom of the deep trench capacitor 110, and extends into the first doped region 102 along an outer wall of the deep trench capacitor 110.

In some embodiments, an ion doping type of the first doped region 102 is the same as that of the second doped region 105. An ion doping dose of the first doped region 102 is less than that of the second doped region 105.

A first metal layer 112 is located on the first dielectric layer 103. The first metal layer 103 is connected with the multiple deep trench capacitors 110.

In some embodiments, the semiconductor structure further includes a through silicon via structure 111. The multiple deep trench capacitors 110 are located on a periphery of the through silicon via structure 111. The through silicon via structure 111 includes a second insulating layer 1114 lining a serrated inner wall, a second buffer layer 1112 located on the second insulating layer 1114, and a second conductive layer 1111 located on the second buffer layer 1114. The second conductive layer 111 is connected with the first metal layer 112.

In some embodiments, the depth of the through silicon via structure 111 ranges from 40 to 60 microns, and the depth of the deep trench capacitors 110 ranges from 10 to 20 microns.

In some embodiments, the through silicon via structure 111 is located at a side of the first doped region 102 (i.e., the structure shown in FIG. 2F) or among the first doped region 102.

In some embodiments, the first metal layer 112 is further connected with one end of the through silicon via structure 111. The other end of the through silicon via structure 111 is connected with a metal bump 115.

The characteristics disclosed in some method or structure embodiments provided in the disclosure may be combined freely without conflicts to obtain new method embodiments or structure embodiments.

The descriptions about the above semiconductor structure embodiments are similar to those about the method embodiments, and beneficial effects similar to those of the method embodiment are achieved. Technical details undisclosed in the semiconductor structure embodiments of the disclosure can be understood with reference to the descriptions about the method embodiments of the disclosure.

The above is only the exemplary embodiments of the disclosure and not intended to limit the scope of protection of the disclosure. Any modifications, equivalent replacements, improvements, and the like made within the spirit and principle of the disclosure shall fall within the scope of protection of the disclosure.

### INDUSTRIAL APPLICABILITY

In the embodiments of the disclosure, first, the first conductive layer in a deep trench capacitor is connected with the first metal layer to form the internal electrode of the deep trench capacitor, and the second doped region at the bottom of the deep trench extends into the first doped region, forming the external electrode of the deep trench capacitor together. The first insulating layer in the deep trench capacitor is equivalent to a dielectric layer between the internal electrode and the external electrode. Since the deep trench includes the serrated inner wall, the surface area of the first insulating layer may be enlarged. Meanwhile, the first conductive layer is arranged conformally on the first insulating layer, so that the surface area of the first conductive layer is also enlarged. Therefore, the opposite area between the external electrode and the internal electrode is enlarged, capacitance of the deep trench capacitor is increased, and the voltage is stabilized. Second, the existence of the high-concentration second doped region reduces the depletion effect of the deep trench capacitor, and stabilizes the capacitance value of the deep trench capacitor. Finally, in the embodiments of the disclosure, the deep trench capacitor is used as a decoupling capacitor, such that the production process is simple, defects are readily to be avoid, and the production efficiency is improved.

What is claimed is:

1. A semiconductor structure, comprising:
a substrate, comprising a first doped region;
a first dielectric layer, located on the substrate;
multiple deep trench capacitors, extending from the first dielectric layer to an inside of the substrate, each of the deep trench capacitors penetrating through the first doped region and comprising a serrated inner wall;
multiple second doped regions, located in the substrate, each of the second doped regions surrounding a bottom of each deep trench capacitor and extending into the first doped region along an outer wall of the deep trench capacitor; and
a first metal layer, located on the first dielectric layer and connected with the multiple deep trench capacitors.

2. The semiconductor structure of claim 1, wherein an ion doping type of the first doped region is the same as an ion doping type of the second doped region.

3. The semiconductor structure of claim 1, wherein an ion doping dose of the first doped region is less an ion doping dose that of the second doped region.

4. The semiconductor structure of claim 1, wherein the serrated inner wall comprises multiple recesses, a length of the recesses in a first direction ranges from 0.2 to 0.6 microns, and a length of the recesses in a second direction ranges from 0.1 to 0.4 microns.

5. The semiconductor structure of claim 1, wherein each of the deep trench capacitors comprises:
a first insulating layer, lining the serrated inner wall;
a first buffer layer, located on the first insulating layer; and
a first conductive layer, located on the first buffer layer,
wherein the first conductive layer is connected with the first metal layer to form an internal electrode of the deep trench capacitor.

6. The semiconductor structure of claim 1, wherein a metal pad is included in the first dielectric layer, and the first metal layer is connected with the first doped region through the metal pad to form an external electrode of the deep trench capacitor.

7. The semiconductor structure of claim 1, further comprising a through silicon via structure, wherein the through silicon via structure is located at a side of the first doped region or among the first doped region.

8. The semiconductor structure of claim 7, wherein the multiple deep trench capacitors are located on a periphery of the through silicon via structure.

9. The semiconductor structure of claim 7, wherein the first metal layer is connected with one end of the through silicon via structure, and another end of the through silicon via structure is connected with a metal bump.

10. The semiconductor structure of claim 7, wherein the through silicon via structure comprises a serrated inner wall.

11. The semiconductor structure of claim 10, wherein the through silicon via structure comprises:
a second insulating layer, lining the serrated inner wall;
a second buffer layer, located on the second insulating layer; and
a second conductive layer, located on the second buffer layer and connected with the first metal layer.

12. The semiconductor structure of claim 7, wherein a depth of the through silicon via structure ranges from 40 to 60 microns, and a depth of the deep trench capacitors ranges from 10 to 20 microns.

13. A method for manufacturing a semiconductor structure, comprising:
providing a substrate, the substrate comprising a first doped region;
forming a first dielectric layer on the substrate;
forming multiple deep trenches, the multiple deep trenches extending from the first dielectric layer to an inside of the substrate, the deep trenches penetrating through the first doped region, and each of the deep trenches comprising a serrated inner wall;
ion doping the substrate through the deep trenches, and performing a thermal treatment to form multiple second doped regions, each of the second doped regions surrounding a bottom of each of the deep trenches and extending into the first doped region along an outer wall of the deep trench;
forming multiple deep trench capacitors by filling the deep trenches; and
forming a first metal layer on the first dielectric layer, the first metal layer being connected with the multiple deep trench capacitors.

14. The method for manufacturing a semiconductor structure of claim 13, further comprising:
forming a through silicon via, wherein forming the deep trenches and the through silicon via comprises:
etching the first dielectric layer and the substrate to form multiple trenches, bottoms of the trenches being at a preset distance from a bottom of the substrate; and
covering a number of the trenches, continuing to etch the exposed trench to penetrate through the substrate so as to form the through silicon via, and simultaneously defining the covered trenches as the deep trenches,
wherein the multiple deep trenches are located on a periphery of the through silicon via, and the through silicon via comprises a serrated inner wall.

15. The method for manufacturing a semiconductor structure of claim 13, wherein forming the multiple deep trench capacitors comprises:
forming a first insulating layer in each deep trench, the first insulating layer lining the serrated inner wall;
forming a first buffer layer on the first insulating layer; and
forming a first conductive layer on the first buffer layer,
wherein the first conductive layer is connected with the first metal layer to form an internal electrode of the deep trench capacitor.

16. The method for manufacturing a semiconductor structure of claim 14, further comprising:
forming a through silicon via structure by filling the through silicon via, wherein forming the through silicon via structure comprises:
forming a second insulating layer in the through silicon via, the second insulating layer lining the serrated inner wall;
forming a second buffer layer on the second insulating layer; and
forming a second conductive layer on the second buffer layer,
wherein the through silicon via structure and the deep trench capacitors are formed at the same time.

17. The method for manufacturing a semiconductor structure of claim 14, wherein a metal pad is formed in the first dielectric layer, and the first metal layer is connected with the first doped region through the metal pad to form an external electrode of the deep trench capacitors.

18. The method for manufacturing a semiconductor structure of claim 14, wherein the first metal layer is further connected with the through silicon via structure.

19. The method for manufacturing a semiconductor structure of claim 13, wherein an ion doping dose of the first doped region is less than an ion doping dose of the second doped region, and an ion doping type of the first doped region is the same as an ion doping type of the second doped region.

20. The method for manufacturing a semiconductor structure of claim 14, wherein the serrated inner wall comprises multiple recesses.
